(19) United States
(12) Patent Application Publication
(10) Pub. No.: US 2011/0244397 A1
(43) Pub. Date: Oct. 6, 2011

(54) Methods of Fabricating a Microarray

(76) Inventors: Myung-Sun Kim, Seoul (KR); Hyo-Jin Yun, Suwon-si (KR); Se-Kyung Baek, Hwaseong-si (KR); Soo-Kyung Kim, Suwon-si (KR); Ji-Yun Ham, Seongnam-si (KR); Young-Ho Kim, Yongin-si (KR)

(21) Appl. No.: 13/079,958

(22) Filed: Apr. 5, 2011

(30) Foreign Application Priority Data
Apr. 5, 2010 (KR) 10-2010-0030945

(51) Int. Cl. G03F 7/20

(52) U.S. Cl. 430/320

(57) ABSTRACT

A method of fabricating a microarray is provided, which includes providing a substrate having a surface that is protected by an acid labile protective group that includes an acetal group represented by formula (1) and has a functional group that can be coupled with a monomer of a probe; applying a photoresist including a photo acid generator to the substrate; selectively exposing the photoresist to deprotect the acid labile protective group that corresponds to an exposed region; removing the photoresist; and coupling the monomer that is combined with the acid labile protective group with the deprotected functional group. Formula (1) has the following structure:

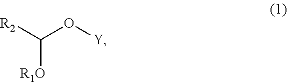

wherein, R1 denotes an alkyl group having 1 to 5 carbon atoms, R2 denotes hydrogen or a methyl group, and Y denotes a monomer or a site coupled with the substrate.

### CROSS-REFERENCE TO RELATED APPLICATIONS

This application is based on and claims priority to Korean Patent Application No. 10-2010-0030945, filed on Apr. 5, 2010 in the Korean Intellectual Property Office. The disclosure of which is incorporated herein by reference in its entirety.

### FIELD OF THE INVENTION

The present invention relates to methods of fabricating a microarray, and more particularly, to methods of fabricating a microarray having an improved reaction yield.

### BACKGROUND

With the development of genome projects, the genome nucleotide sequence of diverse organic bodies has become clear, and thus concerns regarding biopolymer microchips, especially microarrays among the biopolymer microchips, has increased. Microarrays are widely used in the fields of gene expression profiling, genotyping, detection of mutations and polymorphisms such as SNPs, protein and peptide analysis, screening of latent medicines, development and manufacturing of new medicines, and the like.

In general, at present, typical microarrays used are manufactured by exposing a functional group by stripping a protective group fixed to the functional group through light irradiation onto a substrate in a specified region, and by performing the in-situ synthesis of monomers.

Generally, in performing the probe synthesis of microarrays, dimethyloxytrityl (DMT) is used as a protective group that protects a functional group of monomers. However, in this case, it can be difficult to control acids generated by a photo acid generator (PAG).

### SUMMARY

Accordingly, the present inventive concept proposes methods of fabricating a microarray, which can shorten the processing time and improve the reaction yield.

Additional advantages and features of the inventive concept will be set forth in part in the description which follows and in part will become apparent to those having ordinary skill in the art upon examination of the following.

In one embodiment of the present invention, there is provided a method of fabricating a microarray, which includes providing a substrate of which a surface is protected by an acid labile protective group that includes an acetal group and is represented by the following formula (I), and which has a functional group that can be coupled with a first monomer of a probe; providing a photoresist including a photo acid generator onto the substrate; selectively exposing the photoresist to deprotect the acid labile protective group that corresponds to an exposed region; removing the photoresist; and coupling the first monomer that is combined with the acid labile protective group with the deprotected functional group:

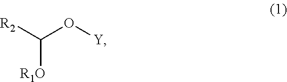

where, R1 denotes an alkyl group having 1 to 5 carbon atoms, R2 denotes hydrogen or a methyl group, and Y denotes a monomer or a site coupled with the substrate.

In another embodiment of the present invention, there is provided a method of fabricating a microarray, which includes providing a substrate including a plurality of probe cell regions, each of which is defined as a deprotected region where a functional group is exposed or a protective region where the functional group is protected by an acid labile protective group; coupling a first monomer, which is combined with the acid labile protective group that includes an acetal group and is represented by the following formula (I), with the functional group of the deprotected region; providing a photoresist including a photo acid generator onto the substrate; selectively exposing the photoresist to deprotect the acid labile protective group that corresponds to the exposed region; removing the photoresist; and coupling a second monomer that is combined with the acid labile protective group with the region in which the acid labile protective group is deprotected:

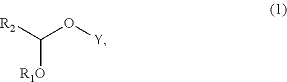

where, R1 denotes an alkyl group having 1 to 5 carbon atoms, R2 denotes hydrogen or a methyl group, and Y denotes a monomer or a site coupled with the substrate.

### BRIEF DESCRIPTION OF THE DRAWINGS

The above and other objects, embodiments, features and advantages of the present invention will be more apparent from the following detailed description taken in conjunction with the accompanying drawings, in which:

FIGS. 1 to 7 are sectional views of intermediate structures explaining a method of fabricating a microarray according to an embodiment of the present invention;

FIGS. 8 to 12 are sectional views of intermediate structures explaining a method of fabricating a microarray according to another embodiment of the present invention;

FIG. 13 is a graph illustrating measured fluorescence intensities in comparison experimental examples where DMT is applied as the acid labile protective group; and

FIG. 14 is a graph illustrating measured fluorescence intensities in experimental examples in which an acetal group is applied as the acid labile protective group.

### DETAILED DESCRIPTION

Hereinafter, various embodiments of the present invention will be described in detail with reference to the accompanying drawings. The aspects and features of the present invention and methods for achieving the aspects and features will be apparent by referring to the embodiments to be described in detail with reference to the accompanying drawings. However, the present invention is not limited to the embodiments disclosed hereinafter, but can be implemented in diverse forms. The matters defined in the description, such as the detailed construction and elements, are nothing but specific details provided to assist those of ordinary skill in the art in a comprehensive understanding of the invention, and the present invention is only defined within the scope of the appended claims. In some embodiments of the present invention, well-known processes, structures, and technologies are not described in detail since they would obscure the invention in unnecessary detail.

The term “connected to” or “coupled to” that is used to designate a connection or coupling of one element to another element includes both a case that an element is “directly connected or coupled to” another element and a case that an element is connected or coupled to another element via still another element. In this case, the term “directly connected to” or “directly coupled to” means that an element is connected or coupled to another element without intervention of any other element. In the entire description of the present invention, the same drawing reference numerals are used for the same elements across various figures. Also, the term “and/or” includes the respective described items and combinations thereof.

Although the terms “first, second, and so forth” are used to describe diverse elements, components and/or sections, such elements, components and/or sections are not limited by the terms. The terms are used only to discriminate an element, component, or section from other elements, components, or sections. Accordingly, in the following description, a first element, first component, or first section may be different from or may be identical to a second element, second component, or second section.

In the following description of the present invention, the terms used are for explaining embodiments of the present invention, but do not limit the scope of the present invention. In the description, a singular expression may include a plural expression unless specially described. The term “comprises” and/or “comprising” used in the description means that one or more other components, steps, operation and/or existence or addition of elements are not excluded in addition to the described components, steps, operation and/or elements. Also, the term “and/or” includes the respective described items and combinations thereof. In the entire description of the present invention, the same drawing reference numerals are used for the same elements across various figures.

Unless specially defined, all terms (including technical and scientific terms) used in the description could be used as meanings commonly understood by those ordinary skilled in the art to which the present invention belongs. In addition, terms that are generally used but are not defined in the dictionary are not interpreted ideally or excessively unless they have been clearly and specially defined.

Hereinafter, a method of fabricating a method of fabricating a microarray according to embodiments of the present invention will be described with reference to the accompanying drawings.

First, with reference to FIGS. 1 to 7, a method of fabricating a microarray according to a first embodiment of the present invention will be described in detail. FIGS. 1 to 7 are sectional views of intermediate structures explaining a method of fabricating a microarray according to an embodiment of the present invention.

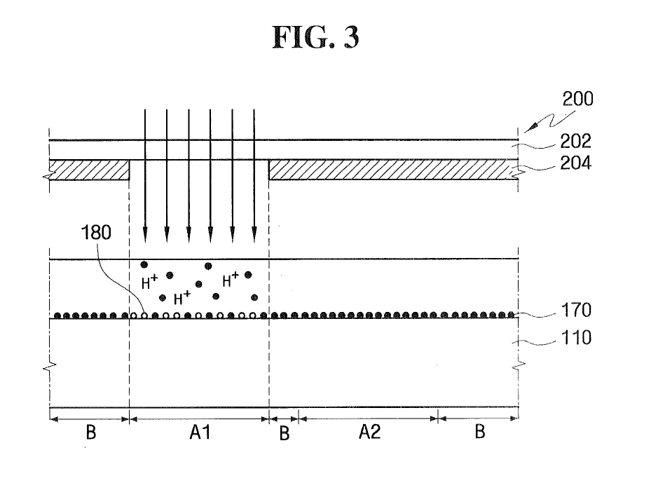

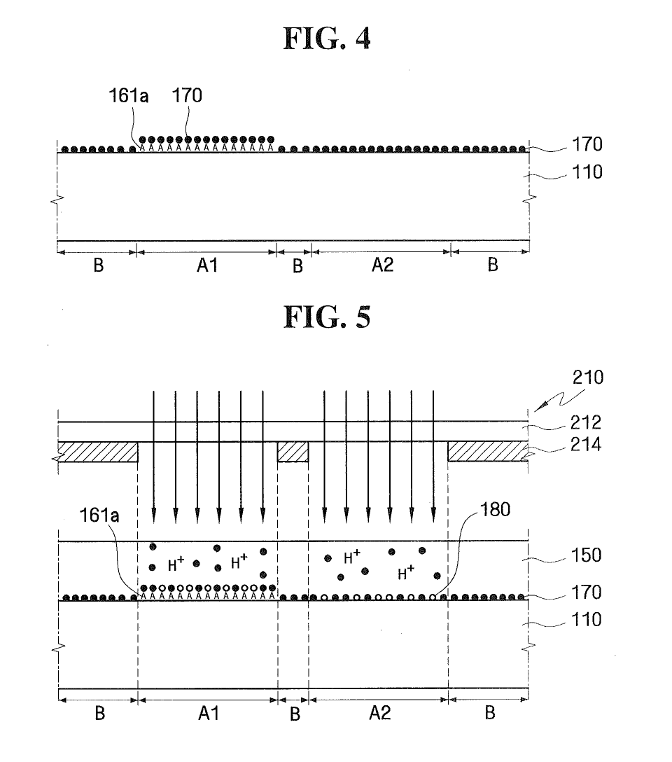

Referring to FIG. 1, a substrate 110 is provided, of which a surface is protected by an acid labile protective group 170 that includes an acetal group and which has a functional group (see 180 in FIG. 3) that can be coupled with a first monomer (see 161a in FIG. 4) of a probe.

The substrate 110 may be a flexible or rigid substrate. An example of the flexible substrate may be a membrane made of nylon, nitrocellulose, and the like, or a plastic film. An example of the rigid substrate may be a silicon substrate or a transparent glass substrate made of glass, crystal, and the like. The silicon substrate or the transparent glass substrate is generally transparent to transmit a visible light and/or UV, and thus, it is favorable to detection using a marker (i.e., a photosensitive marker). The silicon substrate or the transparent glass substrate can be applied to various thin film manufacturing processes and photolithography processes that can be adopted in a semiconductor device manufacturing process or an LCD panel manufacturing process.

On the substrate 110, a large number of probe cell regions 120, with which probes (see 161 and 162 in FIG. 7) are to be coupled, may be formed. The probe cell regions 120 may be formed of substantially safe materials without being hydrolyzed in a hybridization analysis condition, for example, when they are in contact with a phosphate of pH 6 to 9 or TRIS buffer. For example, the probe cell region 120 may be formed of a silicon oxide layer such as a PE-TEOS layer, a high density plasma (HDP) oxide layer, a P—SiH4 oxide layer, a thermal oxidation layer, or the like, silicate such as hafnium silicate, zirconium silicate, or the like, a metal oxynitride layer such as a silicon oxynitride layer, a hafnium oxynitride layer, zirconium oxynitride layer, or the like, a metal oxide layer such as a titanium oxide layer, a tantalum oxide layer, an aluminum oxide layer, a hafnium oxide layer, a zirconium oxide layer, iridium tin oxide (ITO), or the like, metal such as gold, silver, copper, palladium, or the like, or a polymer such as polystyrene, polyacrylic acid, polyvinyl, or the like. Also, the substrate 110 may be made of materials that are utilized in the semiconductor manufacturing process or the LCD manufacturing process.

The surface of the substrate 110 is protected by the acid labile protective group 170 that includes the acetal group.

The acid labile protective group 170 includes the acetal group. For example, the acid labile protective group 170 may be represented by the following formula (I):

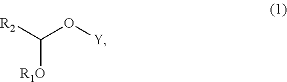

where, R1 denotes an alkyl group having 1 to 5 carbon atoms, R2 denotes hydrogen or a methyl group, and Y denotes a monomer or a site coupled with the substrate.

The acid labile protective group 170 may be used to synthesize the microarray using an in-situ photolithography method. In the case where the acid labile protective group 170 is coupled with the surface of the substrate 110, for example, the functional group 180 formed on the surface of the substrate 110, the substrate 110 may be considered to be protected. The surface of the substrate 110 may be deprotected by acid. Here, the deprotection may mean that the acid labile protective group 170 secedes from the surface of the substrate 110 and the function group 180 on the surface of the substrate 110 is exposed. Such protection and deprotection processes are repeated to form the microarray having a target sequence. The details thereof will be described with reference to the subsequent drawings.

Although not illustrated in the drawings, in some embodiments of the present invention, the substrate 110 may further include a linker which is combined with the functional group (see 180 in FIG. 3) that is formed on each of the probe cell regions A1 and A2, and the functional group 180 may be fixed to each of the probe cell regions A1 and A2 via the linker. The linker may provide a spatial margin in which the probes 161 and 162 freely interact with a target sample, for example, in which the hybridization occurs, via the coupling of the probes 161 and 162 with the target sample. Accordingly, a linker molecule may have a length enough to permit free interaction between the probes 161 and 162 and the target sample, for example, a length of 6 to 59 atoms.

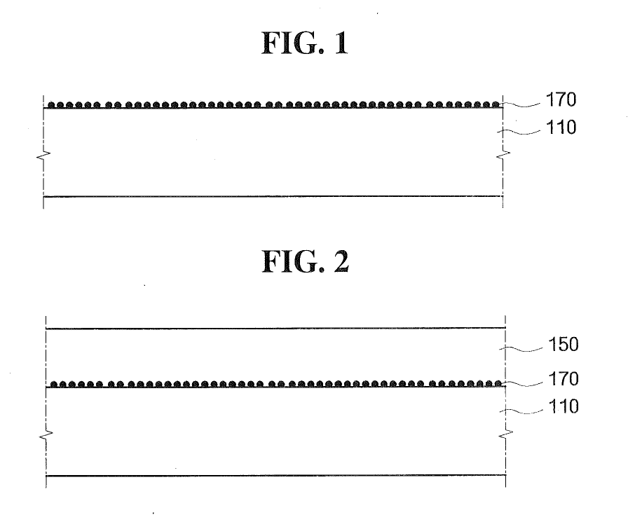

Then, referring to FIG. 2, photoresist 150 including a photo acid generator (PAG) is provided on the substrate 110.

As the photo acid generator, a material that is contained in the photoresist or an organic layer used in a semiconductor manufacturing process or an LCD manufacturing process may be used. For example, the photo acid generator may include a solution that is obtained by dissolving 10 to 50% (w/v) of the photo acid generator in an organic solvent such as N-methylpyrrolidone (NMP) or the like. The photoresist 150 may be provided onto the substrate 110 in a dispensing or spin coating method.

Then, referring to FIG. 3, the acid labile protective group 170 that corresponds to the exposed region A1 is deprotected by selectively exposing the photoresist 150.

First, an optical mask 200, for example, including a light shading pattern 204 may be arranged on the substrate 110. As illustrated in the drawing, the optical mask 200 may include a transparent mask body 202 and the light shading pattern 204 formed on the mask body 202. That is, the light shading pattern 204 of the optical mask 200 may be defined as a light shading region, and a region except for the light shading pattern 204 may be defined as a light transmitting region. In the process of selectively exposing the photoresist 150, various types of optical masks which are different from that as illustrated in the drawing may be used. In some embodiments of the present invention, if the substrate is at least a substantially transparent substrate, the optical mask may be arranged below the substrate. Also, in some other embodiments of the present invention, as modifications of the selective exposure using the optical mask 200, the photoresist 150 may be selectively exposed using an exposure device having a selective exposure capability without arranging a separate optical mask.

When the optical mask 200 is aligned, the exposed region that is not covered by the light shading pattern 204, i.e. the light transmitting region, may be arranged to correspond to the region A1 for coupling a probe or monomer with the exposed region.

More specifically, as illustrated in the drawing, the substrate 110 may include a plurality of probe cell regions A1 and A2 in which the probe is to be formed and a probe cell separation region B in which the probe is not formed. The plurality of probe cell regions A1 and A2 may be separated by the probe cell separation region B. For example, as illustrated in FIG. 3, the surface of the substrate 110 of the probe cell separation region B may be protected by the acid labile protective group 170. That is, the surface of the substrate 110 that corresponds to the probe cell separation region B is not irradiated with light by the light shading pattern 204 of the optical mask 200, and thus, the acid labile protective group 170 can be maintained.

In some embodiments, the coupling of the monomer may be blocked by processing the probe cell separation region B of the substrate 110 in diverse methods. For example, in the probe cell separation region B, a filler having monomer or probe coupling blocking characteristics, for example, fluoride including a fluorine group or polysilicon layer, may fill. On the contrary, the coupling of the probe or monomer with the probe cell separation region B can be prevented by using a capping group which performs inactive capping of the function group that is exposed to the surface of the substrate 110.

That is, the light shading pattern 204 of the optical mask 200 is arranged so as to selectively expose the region corresponding to the probe cell region A1 that is intended to couple with the monomer among the plurality of probe cell regions A1 and A2. Although two probe cell regions A1 and A2 are illustrated in the drawing as the plurality of probe cell regions, this is only for ease of illustration, and three, four, five or more probe cell regions may be provided.

Then, the substrate 110 on which the optical mask 200 is arranged is exposed. As a result, the photo acid generator which is dissolved in the photoresist 150 of the exposed region A1 that corresponds to the exposed region of the substrate 110 is activated by the light having passed through the exposed region of the optical mask 200 to generate acid (H+). The acid (H+) generated by the photo acid generator deprotects the acid labile protective group 170 which exists in the exposed region A1 and is combined with the functional group. Accordingly, a functional group 180 that can be coupled with the oligomer probe or monomer is exposed. In this case, the reactive functional group that is protected by the acid labile protective group 170 may be, but is not limited to, a hydroxyl group, an amino group, a sulfonate group, and the like.

The exposure energy when the photoresist 150 is selectively exposed may be a level that can deprotect the acid labile protective group 170 including the acetal group, for example, in the range of about 100 to 500 mJ, and particularly about 400 mJ. This is relatively large in comparison to the exposure amount which is required when dimethyloxytrityl (DMT) is applied as the acid labile protective group 170 and is about 150 mJ. However, since the acetal group that can be dissolved only by acid does not require a post exposure bake (PEB) process, the entire process time can be greatly shortened.

The acid labile protective group 170 including the acetal group according to an embodiment of the present invention is deprotected by the acid (H+) that is generated in the process of selectively exposing the photoresist 150. More specifically, if the acid (H+) is generated in the photoresist 150 due to the exposure and the acidity of the photoresist 150 that is adjacent to the acid labile protective group 170 has a level that is higher than that of the reference acidity, the acid labile protective group 170 in the exposed region may be deprotected. In this case, the fact that the photoresist 150 is adjacent to the acid labile protective group 170 indicates that the photoresist 150 including the photo acid generator generates the acid (H+) at least due to the provided light and the generated acid (H+) is in the range where it can contribute to the deprotection procedure of the acid labile protective group 170.

In some embodiments of the present invention, the reference acidity in which the acid labile protective group 170 can be deprotected may be in the range of about pH 1 to pH 5, and particularly about pH 2.

As described above, the exposure energy when the photoresist 150 is selectively exposed may be a level that can deprotect the acid labile protective group 170 including the acetal group, and this may indicate that the exposure amount is great enough that the acetal group has a value larger than that of the reference acidity.

As illustrated in FIG. 3, the selective exposure process includes exposing the functional group 180 through deprotection of the acid labile protective group 170 on the exposed region A1 that is a target region with which the monomer is to be coupled. In this case, since main elimination reaction occurs due to the acid (H+) in the acid labile protective group 170 according to an embodiment of the present invention, the acidity of the exposed region A1 may have a value that is larger than that of the non-exposed regions A2 and B. Here, a high acidity may indicate a high acid intensity, for example, a lower pH value.

Since the exposure energy in the process of selectively exposing the photoresist 150 is related to the amount of acid generation of the photo acid generator that is included in the photoresist 150, it can be adjusted so that a difference in acidity between the exposed region A1 and the non-exposed regions A2 and B becomes larger than the reference value. For example, if the acidity of the exposed region A1 is a first acidity and the acidity of the non-exposed regions A2 and B is a second acidity, the photoresist 150 can be selectively exposed so that the ratio of the first acidity to the second acidity becomes about 2:7 to 4:7.

The functional group 180 is exposed by selectively exposing the photoresist 150 that includes the photo acid generator using the optical mask 200 and deprotecting the acid labile protective group 170 by the acid (H+) that is generated by the photo acid generator included in the photoresist 150 on the exposed region A1.

Then, referring to FIG. 4, the photoresist (see 150 in FIG. 3) is removed, and the first monomer 161a that is combined with the acid labile protective group 170 including the acetal group is coupled with the deprotected functional group (see 180 in FIG. 3).

In this case, the removal of the photoresist 150 may be performed in succession to the process of selectively exposing the photoresist 150. Here, the successive performance of the process of selectively exposing the photoresist 150 and the process of removing the photoresist 150 may indicate that a process of heating the photoresist 150 is not included between the process of selectively exposing the photoresist 150 and the process of removing the photoresist 150. That is, a post exposure bake (PEB) process may be performed. Further, in some embodiments of the present invention, the process of removing the photoresist 150 may be performed immediately after the process of selectively exposing the photoresist 150, without performing any other process.

By successively performing the process of selectively exposing the photoresist 150 and the process of removing the photoresist 150, diffusion to the non-exposed regions A2 and B of the acid (H+) generated in the exposure process can be reduced or prevented. Accordingly, the deprotection of the acid labile protective group 170 can be prevented from occurring in the region where the deprotection is not required, i.e. in the non-exposed regions A2 and B. As a result, the exposure of the functional group 180, with which the desired probe or monomer can be coupled, can be more clearly defined on the exposed region A1. That is, the boundary between the exposed region A1 and the non-exposed regions A2 and B can be separated from each other more distinctly.

The exposed functional group 180 may be coupled to a desired probe or monomer 161a. In the case of synthesizing a oligonucleotide probe in-situ as an example, a nucleotide phosphoramidite monomer 161a having any one of adenine (A), guanine (G), thymine (T), cytosine (C), and Uracil (U) as a base can be coupled. In FIG. 4, it is exemplified that a nucleotide phosphoramidite monomer 161a having adenine (A) as a base is coupled. If it is required to additionally synthesize the coupled monomer and another monomer, the monomer that is provided for the coupling may be a nucleotide phosphoramidite monomer 161a combined with the acid labile protective group 170.

As a result of such coupling, the first monomer 161a, which has adenine A as a base and with which the acid labile protective group 170 is combined, may be fixed to the probe cell active A1 that is a target. In this case, since the functional group 180 is not deprotected in the probe cell active A2 that is not a target as described above, fixing of an unnecessary monomer may be avoided. Accordingly, the sequence of the fixed probe may be prevented from becoming compromised or inferior or noise may be prevented or reduced.

Although not illustrated in the drawing, the functional group, which has been exposed in the exposure process but has not been combined with the first monomer 161a, can be inactively capped, for example, using a capping group. For example, if the first monomer 161a is phosphoramidite, the phosphate trimester, which is generated by a combination between the phosphoramidite and the 5′-hydroxy group, is oxidized, and thus, converted into a phosphate structure. In this case, the inactive capping group may use, for example, acetic anhydride and/or N-methylimidazole. Also, the oxidizing agent may, for example, be iodine.

Referring to FIG. 5, the photoresist 150 which includes the photo acid generator is provided on the substrate 110 that is coupled with the first monomer 161a, and the acid labile protective group 170 that corresponds to the exposed regions A1 and A2 is deprotected by selectively exposing the photoresist 150 to expose the functional group 180.

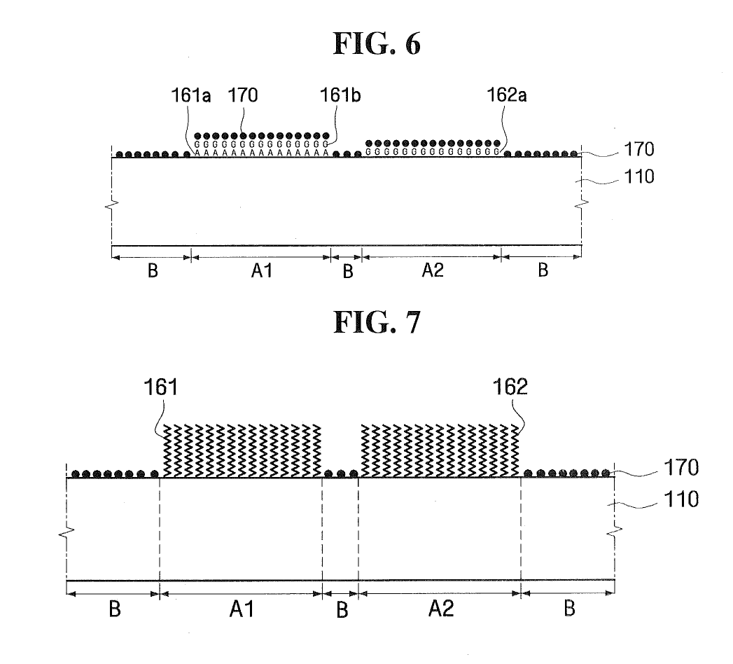

As described above with reference to FIG. 3, a body 212 of the optical mask 210 and the light shading pattern 214 may be arranged on the photoresist 150 that includes the photo acid generator so as to correspond to the regions A1 and A2 to be coupled with the second monomer 161b and 161a as illustrated in FIG. 6. Accordingly, acid (H+) occurs in the selectively exposed regions A1 and A2 of the photoresist 150, and the acid labile protective group 170 that includes the acetal group is deprotected due to the generated acid (H+) to expose the functional group 180.

Referring to FIG. 6, the photoresist 150 is removed, and the second monomers 161b and 162a, which are combined with the acid labile protective group 170 that includes the acetal group, are coupled with the deprotected functional group 180. At this time, as described above, the process of removing the photoresist 150 is performed in succession to the process of selectively exposing the photoresist 150, and thus, diffusion of the acid (H+) generated in the selective exposure process may be reduced or prevented.

As illustrated in FIG. 7, by repeatedly performing the selective deprotecting process and the monomer coupling process, a plurality of probes coupled with the probe cell regions A1 and A2 can be formed.

Accordingly, a plurality of probes 161 and 162 is formed on the plurality of probe cell regions A1 and A2 on the substrate 110, and the plurality of probe cell regions A1 and A2 can be physically and/or chemically separated by the probe cell separation region B.

The plurality of probes 161 and 162 fixed to the plurality of probe cell regions A1 and A2 may be, for example, oligomer probes. In this case, the oligomer may be called a polymer that includes two or more covalently-bonded monomers. The oligomer may include about 2 to 500 monomers, and preferably about 5 to 300 monomers. Also, the oligomer may include about 2 to 100 monomers. Further, the monomer may be a nucleoside, nucleotide, amino acid, or peptide in accordance with the type of probe.

The nucleoside and nucleotide may include not only the known purine and pyrimidine bases but also methylated purine or pyrimidine, acylated purine or pyrimidine, and the like. Also, the nucleoside and nucleotide may include not only known ribose and deoxyribose sugars but also modified sugars in which one or more hydroxyl groups are replaced with halogen atoms or an aliphatic group or are combined with functional groups such as ether, amine, and the like.

The amino acid may include not only L-, D- and nonchiral amino acids but also unnatural amino acids, modified amino acids or amino acid analogs.

A peptide refers to a compound having an amide bond between a carboxyl group of an amino acid and an amino group of another amino acid.

Further, as described above, the probes 161 and 162 may be coupled to the substrate 110 via a linker (not illustrated). The linker may provide a spatial margin in which the probes 161 and 162 freely interact with a target sample, for example, in which the hybridization occurs.

According to a microarray according to an embodiment of the present invention, the acid labile protective group can be deprotected by selectively exposing the photoresist that includes the photo acid generator with energy that is greater than the reference energy using the acid labile protective group that includes the acetal group. More specifically, since the deprotection of the acid labile protective group that includes the acetal group is possible without performing a separate bake process after the photoresist is exposed, the unnecessary diffusion of the acid that is generated by the photo acid generator can be reduced or prevented. Accordingly, the boundary of whether the acid labile protective groups of the exposed region and the non-exposed regions are deprotected is more clearly formed, and thus, a microarray having an improved reaction yield can be fabricated.

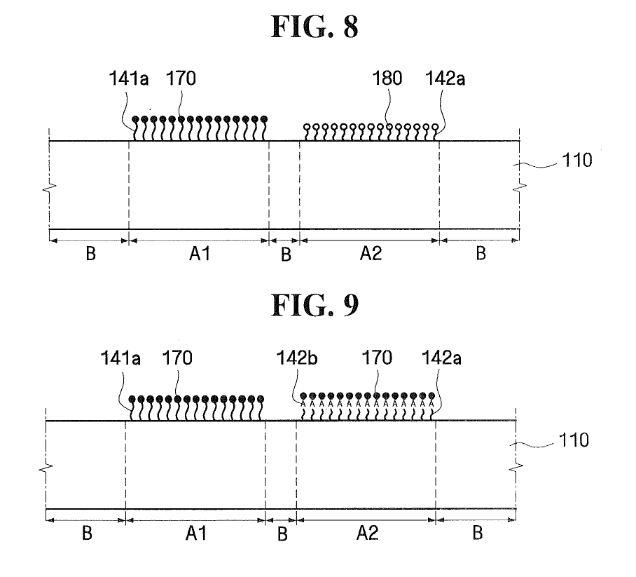

Hereinafter, with reference to FIGS. 8 to 12, a method of fabricating a microarray according to another embodiment of the present invention will be described. FIGS. 8 to 12 are sectional views of intermediate structures explaining a method of fabricating a microarray according to another embodiment of the present invention.

The following array fabricating method according to another embodiment of the present invention is different from the above-described embodiments in which the surface of the substrate 110 is protected by the acid labile protective group including the acetal acid on the point that one portion of the plurality of probe cell regions A1 and A2 of the substrate 110 is an exposed deprotected region A2 and the other portion thereof is defined as a protected region A1 that is protected by the acid labile protective group 170. Hereinafter, for convenience in explanation, the detailed explanation of the elements which are substantially similar to those in the above-described embodiments will be omitted or simplified.

Referring to FIG. 8, the substrate 110 includes a plurality of probe cell regions A1 and A2, and the plurality of probe cell regions A1 and A2 are defined as the deprotected region A2 in which the functional group 180 is exposed and the protected region A1 in which the functional group 180 is protected by the acid labile protective group. More specifically, the protected region A1 refers to a region in which a first preliminary probe 141a that is protected by the acid labile protective group 170 is coupled, and the deprotected region A2 refers to a region in which a second preliminary probe 142a having an exposed functional group 180 is coupled.

The plurality of probe cell regions A1 and A2 may be separated by the probe cell separation region B. The probe cell separation region B may be protected by the acid labile protective group to be inactivated as illustrated in FIGS. 1 to 7, or may not form the acid labile protective group as illustrated in FIG. 8. In this case, by performing the inactivation process, for example, the capping process or plasma process, with respect to the surface of the substrate 110 that corresponds to the probe cell separation region B, the monomer (see 142b in FIG. 9) provided in the following process may not be coupled.

Then, referring to FIG. 9, the first monomer 142b that is combined with the acid labile protective group 170 including the acetal group is coupled with the functional group (see 180 in FIG. 8) on the deprotected region A2.

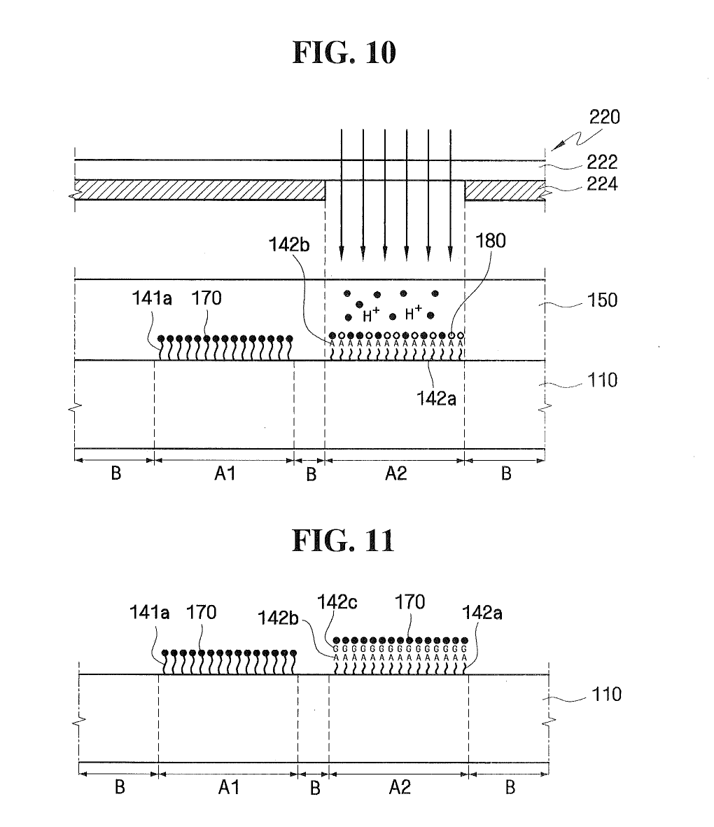

Referring to FIG. 10, the photoresist 150 including the photo acid generator is provided onto the substrate 110, and by selectively exposing the photoresist 150, the acid labile protective group 170 that corresponds to the exposed region A2 is deprotected.

Referring to FIG. 11, the photoresist 150 is removed, and the second monomer 142c that is combined with the acid labile protective group 170 including the acetal group is coupled with the region A2 where the acid labile protective group 170 is deprotected. More specifically, the second monomer 142c may be coupled with the exposed functional group (see 180 in FIG. 10) of the first monomer 142a.

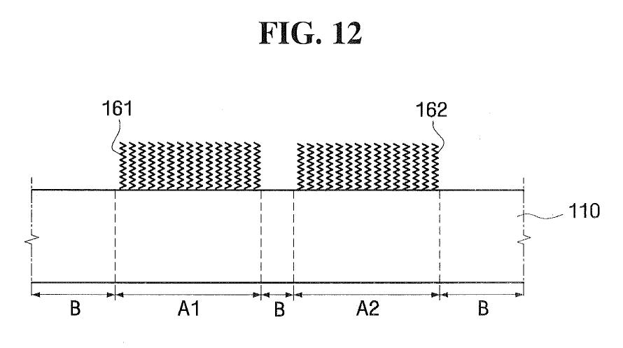

Referring to FIG. 12, by repeatedly performing the distribution of the photoresist 150 including the photo acid generator, the selective exposing of the photoresist 150, the removal of the photoresist 150, and the coupling of the monomer with the functional group 180, a plurality of probes 161 and 162 can be formed on a plurality of probe cell regions A1 and A2. In this case, the plurality of probes 161 and 162 formed on the same probe cell region A1 or A2 may include the same sequence. Further, the respective probes 161 and 162 formed on the different probe cell regions A1 and A2 may have different sequences, or may have the same sequence according to circumstances.

According to the method of fabricating the microarray according to another embodiment of the present invention, monomers combined with the acid labile protective group including the acetal group are selectively combined with the probe cell region rather than forming the acid labile protective group on the substrate that corresponds to the probe cell separation region, and thus the boundary between the probe cell separation region and the probe cell region can be formed more distinctly.

The detailed contents of the embodiments of the present invention will be described through the following detailed experimental examples. The contents which have not been described herein can be technically analogized by those skilled in the art, and thus the detailed explanation thereof will be omitted.

### Experimental Examples

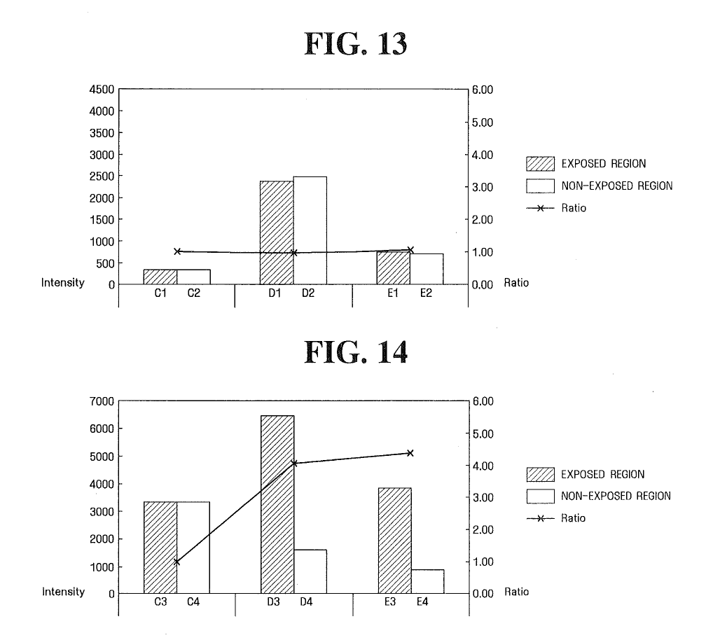

Referring to FIGS. 13 and 14, the photoresist including different types of photo acid generators was applied to the substrate, in which the acid labile protective group including dimethoxytrityl (DMT) and the acetal group were coupled, and then the photoresist was removed by performing the selective exposure. The degree of deprotection of the acid labile protective group was confirmed by measuring the generation of —OH groups through fluorescence intensities.

FIG. 13 is a graph illustrating measured fluorescence intensities in comparison to experimental examples where DMT is applied as the acid labile protective group, and FIG. 14 is a graph illustrating measured fluorescence intensities in experimental examples in which an acetal group is applied as the acid labile protective group.

In the case of “C”, a trichloroacetic acid (TCA) was included in the photoresist, and in the case of “D”, a 10-camphor sulfonic acid was included in the photoresist. In the case of “E”, octyl sulfonic acid was included in the photoresist.

Referring to FIGS. 13 and 14, in the case of using the TCA, an exposed region C1 and a non-exposed region C2 in the comparative experimental example and an exposed region C3 and a non-exposed region C4 in the experimental example showed fluorescence intensities of the same level. It was determined that acid was generated in both the exposed region and the non-exposed region, regardless of the selective exposure, since the TCA included acid, and thus, the acid labile protective group was deprotected.

However, in the case of “D” and “E”, in the comparative experimental example, there was no great difference in fluorescence intensity between the exposed regions D1 and Ea and the non-exposed regions D2 and E2. In contrast, in the experimental example, the fluorescence intensity of the exposed regions D3 and E3 appeared to be greatly higher than the fluorescence intensity of the non-exposed regions D4 and E4, and their ratio was about 4:1 to 4.5:1.

Accordingly, in successively performing the selective exposure process and the photoresist removing process, in the case of applying DMT as the acid labile protective group, the acid labile protective group of the exposed region was not stably deprotected, whereas in the case of the acid labile protective group including the acetal group, the acid labile protective group was stably deprotected even without the post exposure bake process. In addition, the fluorescence intensity of the exposed region was greatly higher than the fluorescence intensity of the non-exposed region thereby indicating that the reaction yield was greatly improved.

Although embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A method of fabricating a microarray, comprising:
applying a photoresist comprising a photo acid generator to a substrate that is protected by an acid labile protective group, wherein the acid labile group comprises a functional group that can be coupled with a monomer of a probe and is represented by formula (I): 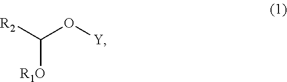
wherein, R1 is an alkyl group having 1 to 5 carbon atoms, R2 is hydrogen or a methyl group, and Y is a monomer or a site coupled with the substrate;
exposing the photoresist to deprotect the acid labile protective group that corresponds to an exposed region;
removing the photoresist; and
coupling the monomer combined with the acid labile protective group with the deprotected functional group.

2. The method of claim 1, further comprising sequentially removing the photoresist after exposing the photoresist.

3. The method of claim 2, wherein the photoresist is not heated between exposing the photoresist and removing the photoresist.

4. The method of claim 1, wherein exposing the photoresist comprises exposing the photoresist with a first-level energy that deprotects the acid labile protective group comprising the acetal group.

5. The method of claim 1, wherein the substrate comprises a plurality of probe cell regions and a probe cell separation region, and the plurality of probe cell regions are separated by the probe cell separation region.

6. The method of claim 5, wherein the photoresist on a region to be coupled with a monomer among the plurality of probe cell regions has a first acidity level and the photoresist on the probe cell separation region has a second acidity level, and wherein exposing the photoresist comprises exposing the photoresist so that the ratio of the first acidity level to the second acidity level becomes 2:7 to 4:7.

7. The method of claim 5, wherein exposing the photoresist comprises exposing the photoresist using a mask that comprises a light transmitting region and a light shading region and arranging the mask so that the light transmitting region corresponds to at least a portion of the plurality of probe cell regions.

8. The method of claim 1, wherein the substrate further comprises a linker that is coupled to the functional group formed on the plurality of probe cell regions;
wherein the functional group is fixed to the plurality of probe cell regions via the linker.

9. The method of claim 1, wherein the protection and deprotection processes are performed repeatedly.

10. A method of fabricating a microarray, comprising:
coupling a first monomer combined to an acid labile protective group with a functional group of a deprotected region of a substrate comprising a plurality of probe cell regions wherein the deprotected region comprises an area where a functional group is exposed or a protective region where the functional group is protected by the acid labile protective group, and wherein the acid labile group comprises a functional group and is represented by formula (I): 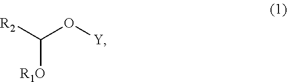
wherein, R1 is an alkyl group having 1 to 5 carbon atoms, R2 is hydrogen or a methyl group, and Y is a monomer or a site coupled with the substrate;
applying a photoresist comprising a photo acid generator to the substrate;
exposing the photoresist to deprotect the acid labile protective group that corresponds to an exposed region;
removing the photoresist; and
coupling a second monomer that is combined with an acid labile protective group of formula (I) with a region in which the acid labile protective group is deprotected.

11. The method of claim 10, further comprising sequentially removing the photoresist after exposing the photoresist.

12. The method of claim 10, wherein the photoresist is not heated between exposing the photoresist and removing the photoresist.

13. The method of claim 10, wherein exposing the photoresist comprises exposing the photoresist with a first-level energy level that deprotects the acid labile protective group comprising the acetal group.

14. The method of claim 10, wherein exposing the photoresist comprises exposing the photoresist using a mask that comprises a light transmitting region and a light shading region and arranging the mask so that the light transmitting region corresponds to at least a portion of the plurality of probe cell regions.

15. The method of claim 10, wherein the plurality of probe cell regions are separated by the probe cell separation region.

16. The method of claim 15, wherein the photoresist on the plurality of probe cell regions has a first acidity level and the photoresist on the probe cell separation region has a second acidity level, and wherein exposing the photoresist comprises exposing the photoresist so that the ratio of the first acidity level to the second acidity level is 2:7 to 4:7.

17. The method of claim 10, wherein the substrate further comprises a linker that is coupled with the functional group formed on the plurality of probe cell regions;
wherein the functional group is fixed to the plurality of probe cell regions via the linker.

18. The method of claim 10, wherein the functional group of the substrate is coupled with one end of the plurality of monomers sequentially coupled, and the other end thereof is fixed to the substrate.

19. A method of fabricating a microarray, comprising:
applying a photoresist comprising a photo acid generator to a substrate that is protected by an acid labile protective group, wherein the acid labile protective group comprises a sulfonic acid protective group and can be coupled with a monomer of a probe;
exposing the photoresist to deprotect the sulfonic acid protective group that corresponds to an exposed region;
removing the photoresist; and
coupling the monomer combined with the sulfonic acid protective group with the deprotected functional group.
